(19) United States
(12) Patent Application Publication
(10) Pub. No.: US 2026/0068504 A1
(43) Pub. Date: Mar. 5, 2026

(54) DISPLAY DEVICE AND ELECTRONIC DEVICE INCLUDING THE SAME

(71) Applicant: Samsung Display Co., Ltd., Yongin-Si (KR)

(72) Inventors: CHAUNGI CHOI, Yongin-si (KR); GEE-BUM KIM, Yongin-si (KR); BOKWANG SONG, Yongin-si (KR)

(21) Appl. No.: 19/217,234

(22) Filed: May 23, 2025

(30) Foreign Application Priority Data
Aug. 28, 2024 (KR) 10-2024-0116010

(51) Int. Cl. H10K 59/80; H10K 102/00

(52) U.S. Cl. CPC H10K 59/879; H10K 59/878; H10K 2102/351

(57) ABSTRACT

A display device is disclosed that includes a substrate, a pixel layer disposed on the substrate and including an organic light-emitting diode, an encapsulation member that seals the pixel layer, and a refractive layer disposed on the encapsulation member and including first and second refractive patterns. The second refractive pattern includes a second penetration area through which a first portion of light emitted from the organic light-emitting diode passes and a second reflective side surface that reflects a second portion of the light emitted by the organic light-emitting diode. The first and second portions of the light emitted from the organic light-emitting diode forming transmitted light. The first refractive pattern is disposed to overlap the second refractive pattern and includes a first penetration area through which a first portion of the transmitted light passes and a first reflective side surface that reflects a second portion of the transmitted light.

### CROSS-REFERENCE TO RELATED APPLICATION

This application is based on and claims priority under 35 U.S.C. § 119 to Korean Patent Application No. 10-2024-0116010, filed on Aug. 28, 2024, in the Korean Intellectual Property Office, the disclosure of which is incorporated by reference herein in its entirety.

### BACKGROUND

### 1. Field

The disclosure relates to a display device and electronic device including the same.

### 2. Description of the Related Art

Recently, display devices are being used for various purposes. Also, as display devices become thinner and lighter, their range of use is expanding. As display devices are utilized in various fields, the demand for display devices that provide high-quality images is increasing.

Display elements included in a display device may emit light and display images. Light emitted from a display device may travel in a direction perpendicular to the front surface of the display device or in a direction oblique to the front surface of the display device.

The above-stated information disclosed in the background technology of the disclosure is only intended to improve understanding of the background of the disclosure and therefore may include information that does not constitute background art.

### SUMMARY

The disclosure may provide a display device and electronic device including the same with a controllable viewing angle.

However, the technical problems to be solved by the disclosure are not limited to the problems described above, and other problems not mentioned may be clearly understood by one of ordinary skill in the art from the description of the disclosure described below.

Additional aspects will be set forth in part in the description which follows and, in part, will be apparent from the description, or may be learned by practice of the presented embodiments of the disclosure.

An embodiment of a display device includes a substrate, a pixel layer disposed on the substrate and including a pixel, the pixel including an organic light-emitting diode, an encapsulation member that seals the pixel layer, and a refractive layer disposed on the encapsulation member and including a second refractive pattern and a first refractive pattern, wherein the second refractive pattern includes a second penetration area through which a first portion of light emitted from the organic light-emitting diode passes and a second reflective side surface that reflects a second portion of light from the organic light-emitting diode, the first and second portions of the light emitted from the organic light-emitting diode forming transmitted light, and the first refractive pattern is disposed to overlap the second refractive pattern and includes a first penetration area through which a first portion of the transmitted light passes and a first reflective side surface that reflects a second portion of the transmitted light.

The second refractive pattern may be disposed between the encapsulation member and the first refractive pattern.

The second refractive pattern may be disposed to be spaced apart from the first refractive pattern.

The display device may further include a first light-blocking pattern disposed to overlap the second refractive pattern or the first refractive pattern.

The first refractive pattern or the second refractive pattern may be disposed to cover the first light-blocking pattern.

The first reflective side surface and the second reflective side surface may each include an inclined surface.

The first penetration area and the second penetration area may each overlap an emission area of the organic light-emitting diode.

The first penetration area and the second penetration area may overlap each other.

A width of the first penetration area may be identical to a width of the second penetration area.

A width of the first penetration area may be greater than a width of the second penetration area.

The display device may further include a first planarizing layer formed to cover the first refractive pattern.

A refractive index of the first planarizing layer may be different from a refractive index of the first refractive pattern.

The display device may further include a second planarizing layer formed to cover the second refractive pattern.

A refractive index of the second planarizing layer may be different from a refractive index of the second refractive pattern.

A width of the first refractive pattern between the pixel and an adjacent pixel may be identical to a width of the second refractive pattern between the pixel and the adjacent pixel.

A width of the first refractive pattern between the pixel and an adjacent pixel may be smaller than a width of the second refractive pattern between the pixel and the adjacent pixel.

The width of the first refractive pattern between the pixel and an adjacent pixel may be greater than the width of the first light-blocking pattern between the pixel and the adjacent pixel.

The display device may further include a third refractive pattern between the second refractive pattern and the encapsulation member.

The second refractive pattern may cover a second light-blocking pattern.

The first refractive pattern may cover a first light-blocking pattern, and a width of the second light-blocking pattern between the pixel and an adjacent pixel is identical to a width of the first light-blocking pattern between the pixel and the adjacent pixel.

An embodiment of an electronic device includes a display module, a processor, a memory and a power module, wherein the display module includes a substrate, a pixel layer disposed on the substrate and comprising a pixel, the pixel comprising an organic light-emitting diode, an encapsulation member that seals the pixel layer, and a refractive layer disposed on the encapsulation member and comprising a second refractive pattern and a first refractive pattern, wherein the second refractive pattern comprises a second penetration area through which a first portion of light emitted from the organic light-emitting diode passes and a second reflective side surface that reflects a second portion of the light emitted from the organic light-emitting diode, the first and second portions of light emitted from the organic light-emitting diode form transmitted light, and the first refractive pattern is disposed to overlap the second refractive pattern and comprises a first penetration area through a first portion of the transmitted light passes and a first reflective side surface that reflects a second portion of the transmitted light.

### BRIEF DESCRIPTION OF THE DRAWINGS

The following drawings attached to this specification illustrate preferred embodiments of the disclosure and, together with the detailed description of the disclosure described below, serve to further understand the technical idea of the disclosure; therefore, the disclosure should not be interpreted as being limited to matters described in such drawings, in which:

FIG. 1 is a schematic perspective view of a display device according to an embodiment of the disclosure;

FIG. 2 is a schematic cross-sectional view of an example of a cross-section along a line I-I′ of FIG. 1;

FIG. 3 is a schematic plan view of an example of a portion of the display device of FIG. 1;

FIG. 4 is a circuit diagram showing an example of one pixel of the display device of FIG. 1;

FIG. 5 is a schematic cross-sectional view of an example of a portion of a cross-section along a line II-II′ of FIG. 1;

FIG. 6 is a schematic cross-sectional view of an example of a portion of a cross-section along a line II-II′ of FIG. 1;

FIG. 7 is a schematic cross-sectional view of an example of a portion of a cross-section along the line II-II′ of FIG. 1;

FIG. 8 is a schematic cross-sectional view of an example of a portion of a cross-section along the line II-II′ of FIG. 1;

FIG. 9 is a graph showing relative brightness according to viewing angles;

FIG. 10 is a schematic cross-sectional view of an example of a portion of a cross-section along the line II-II′ of FIG. 1;

FIG. 11 is a schematic cross-sectional view of an example of a portion of a cross-section along the line II-II′ of FIG. 1;

FIG. 12 is a graph showing relative efficiency according to distances between refractive patterns; and

FIG. 13 is a schematic cross-sectional view of an example of a portion of a cross-section along the line II-II′ of FIG. 1.

FIG. 14 is a block diagram of an electronic device according to an embodiment.

FIG. 15 illustrates schematic views of electronic devices according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Expressions such as “at least one of,” when preceding a list of elements, modify the entire list of elements and do not modify the individual elements of the list.

The disclosure may include various embodiments and modifications, and embodiments thereof will be illustrated in the drawings and will be described herein in detail. The effects and features of the disclosure and the accompanying methods thereof will become apparent from the following description of the embodiments, taken in conjunction with the accompanying drawings. However, the disclosure is not limited to the embodiments described below, and may be embodied in various modes.

It will be understood that although the terms “first”, “second”, etc. may be used herein to describe various elements, these elements should not be limited by these terms. These elements are only used to distinguish one element from another.

As used herein, the singular forms “a,” “an” and “the” are intended to include the plural forms as well, unless the context clearly indicates otherwise.

It will be further understood that the terms “comprises” and “includes” (as well as variations such as “comprising”) used herein specify the presence of stated features or components, but do not preclude the presence or addition of one or more other features or components.

It will be understood that when a unit, region, or component is referred to as being “formed on” another layer, region, or component, it can be directly or indirectly formed on the other unit, region, or component. That is, for example, intervening layers, regions, or components may be present.

In the examples below, terms such as connect or combine do not necessarily imply a direct or fixed connection or combination of two members, unless the context clearly indicates otherwise, and do not exclude the presence of another member between the two members.

Sizes of elements in the drawings may be exaggerated for convenience of explanation. In other words, since sizes or thicknesses of components in the drawings are arbitrarily illustrated for convenience of explanation, the following embodiments are not limited thereto.

Reference will now be made in detail to embodiments, examples of which are illustrated in the accompanying drawings. In the drawings, the same elements are denoted by the same reference numerals, and a repeated explanation thereof will not be given.

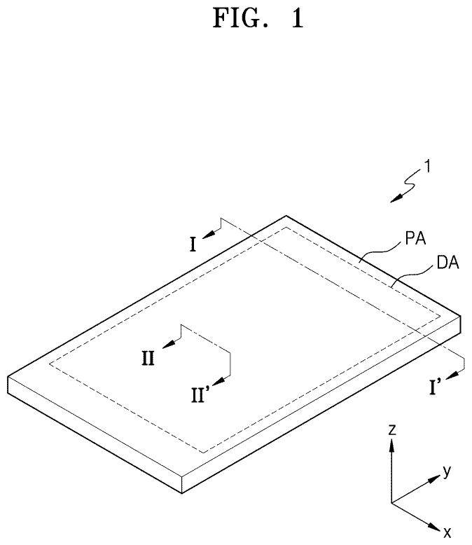

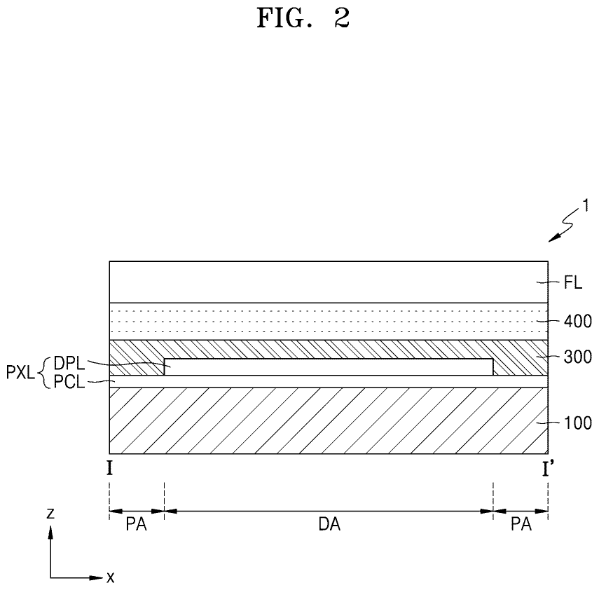

FIG. 1 is a schematic perspective view of a display device according to an embodiment of the disclosure. FIG. 2 is a schematic cross-sectional view of an example of a cross-section along a line I-I′ of FIG. 1.

Referring to FIG. 1, a display device 1 according to an embodiment of the disclosure may include a display area DA and a peripheral area PA. The peripheral area PA is arranged outside the display area DA to surround the display area DA. Various wires and driving circuits for transmitting electrical signals to be applied to the display area DA may be arranged in the peripheral area PA. The display device 1 may provide a predetermined image by using light emitted from a plurality of pixels arranged in the display area DA. Although not shown, the display device 1 may be bent by including a bent area in a portion of the peripheral area PA.

The display device 1 may be a display device such as an organic light-emitting display device, an inorganic light-emitting display device (or inorganic EL display device), or a quantum dot light-emitting display device. Descriptions below will be given based on an organic light-emitting display device as an example. The display device 1 may be implemented as various types of electronic devices such as a mobile phone, a laptop computer, or a smart watch.

As shown in FIG. 2, the display device 1 may include a substrate 100, a pixel layer PXL including an organic light-emitting diode on the substrate 100, an encapsulation member 300 that encapsulates the pixel layer PXL, a refractive layer 400 on the encapsulation member 300, and a functional layer FL on the refractive layer 400, wherein the substrate 100, the pixel layer PXL, the encapsulation member 300, the refractive layer 400, and the functional layer FL are sequentially stacked in the thickness-wise direction (z direction).

The substrate 100 may include a glass material or a polymer resin. For example, the substrate 100 may include a glass material containing SiO2 as a main component or may include various materials having flexible or bendable properties, e.g., a resin such as a reinforced plastic. Although not shown, the substrate 100 may be bent by including a bent area in a portion of the peripheral area PA.

The pixel layer PXL may be disposed on the substrate 100. The pixel layer PXL may include a display element layer DPL including display elements respectively arranged in pixels and a pixel circuit layer PCL including pixel circuits and insulation layers respectively arranged in the pixels. The display element layer DPL is disposed on an upper layer of the pixel circuit layer PCL, and a plurality of insulation layers may be arranged between pixel circuits and display elements. Some of wires and insulation layers of the pixel circuit layer PCL may extend to the peripheral area PA.

The encapsulation member 300 may be a thin-film encapsulation layer. The thin-film encapsulation layer may include at least one inorganic encapsulation layer and at least one organic encapsulation layer. When the display device 1 includes the substrate 100 including a polymer resin and the encapsulation member 300, which is a thin film-encapsulating layer including an inorganic encapsulating layer and an organic encapsulating layer, the flexibility of the display device 1 may be improved.

The refractive layer 400 may control the path of light emitted from the display elements of the display element layer DPL, thereby improving the emission efficiency of the display device 1. As described below, the refractive layer 400 may change the path of light emitted from the display elements to increase the light extraction efficiency of the display device 1.

The functional layer FL may include a polarization layer. From light emitted from the display elements of the display element layer DPL, the polarization layer transmits a portion of light having an electric field in the direction as the polarization axis and absorbs or reflects light the portion of light having an electric field perpendicular to the polarization axis. Also, the functional layer FL may further include an optical film, a window, etc. for reflecting external light.

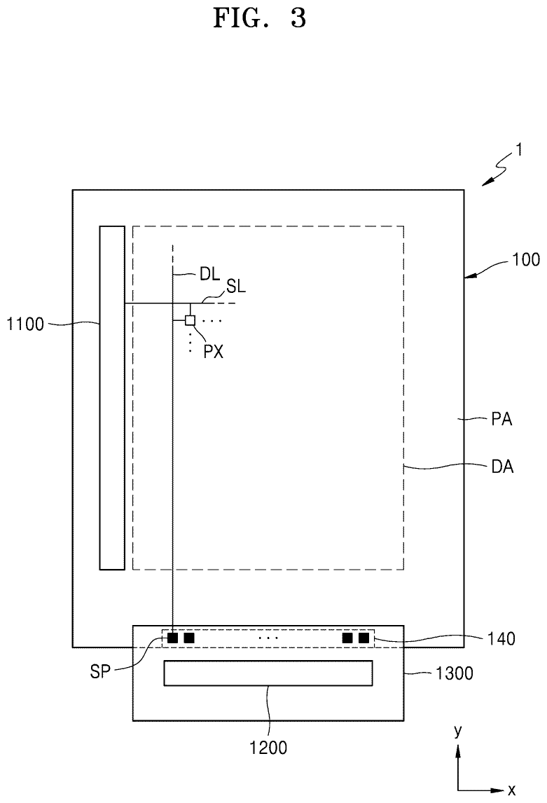

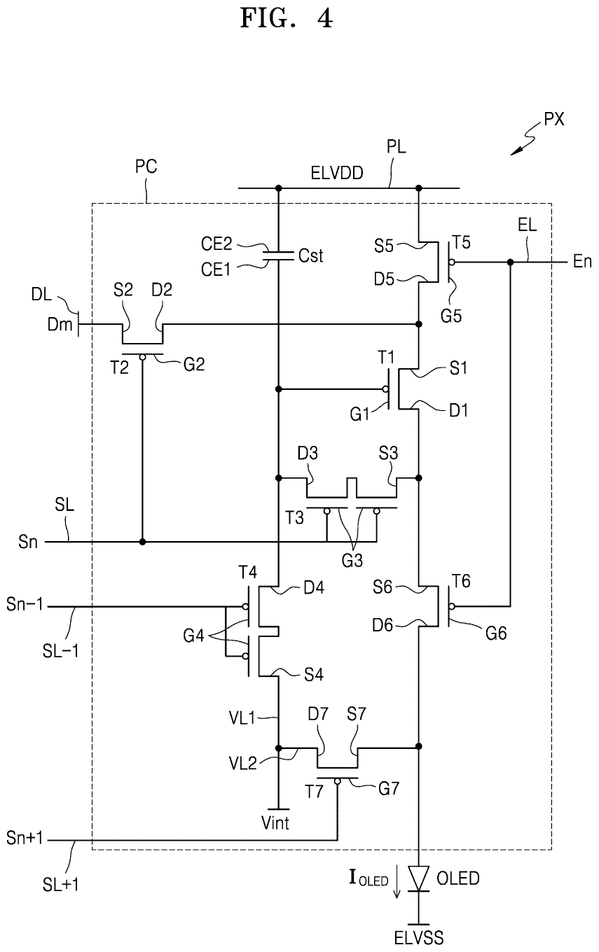

FIG. 3 is a schematic plan view of an example of a portion of the display device of FIG. 1, and FIG. 4 is a circuit diagram illustrating an example of a pixel of the display device of FIG. 1.

Referring to FIG. 3, the substrate 100 may include the display area DA and the peripheral area PA. The peripheral area PA may be located outside the display area DA and may surround the display area DA.

In the display area DA on the upper portion of the substrate 100, a plurality of pixels PX may be arranged in a predetermined pattern in a first direction (x direction, row-wise direction) and a second direction (y direction, column-wise direction).

In the peripheral area PA on the upper portion of the substrate 100, a scan driver 1100 that provides a scan signal to each pixel PX, a data driver 1200 that provides a data signal to each pixel PX, and main power lines (not shown) for providing a driving voltage ELVDD (refer to FIG. 4) and a common voltage ELVSS (refer to FIG. 4) may be arranged. A pad unit 140 in which a plurality of signal pads SP respectively connected to data lines DL are arranged may be located in the peripheral area PA on the upper portion of the substrate 100.

The scan driver 1100 may include an oxide semiconductor TFT gate driver circuit (OSG) or an amorphous silicon TFT gate driver circuit (ASG). Although FIG. 3 shows an example in which the scan driver 1100 is located adjacent to one side of the substrate 100, the scan driver 1100 may be located adjacent to two sides of the substrate 100 facing each other, according to embodiments.

FIG. 3 illustrates a chip on film (COF) scheme in which the data driver 1200 is disposed on a film 1300 electrically connected to the signal pads SP arranged on the upper portion of the substrate 100. According to another embodiment, the data driver 1200 may be disposed directly on the substrate 100 in a chip on glass (COG) scheme or a chip on plastic (COP) scheme. The data driver 1200 may be electrically connected to a flexible printed circuit board (FPCB).

Referring to FIG. 4, a pixel PX may include a pixel circuit PC and an organic light-emitting device OLED electrically connected to the pixel circuit PC.

The pixel circuit PC may include a plurality of transistors T1 to T7 and a storage capacitor Cst, as shown in FIG. 4. The transistors T1 to T7 and the storage capacitor Cst may be connected to signal lines SL, SL−1, SL+1, EL, and DL, a first initialization voltage line VL1, a second initialization voltage line VL2, and a driving voltage line PL.

The signal lines SL, SL−1, SL+1, EL, and DL may include a scan line SL transmitting a scan signal Sn, a previous scan line SL−1 transmitting a previous scan signal Sn−1 to a first initialization transistor T4, a subsequent scan line SL+1 transmitting a subsequent scan signal Sn+1 to a second initialization transistor T7, an emission control line EL transmitting an emission control signal En to an operation control transistor T5 and an emission control transistor T6, and a data line DL crossing the scan line SL and transmitting a data signal Dm. The driving voltage line PL may transmit the driving voltage ELVDD to a driving transistor T1, the first initialization voltage line VL1 may transmit an initialization voltage Vint to the first initialization transistor T4, and the second initialization voltage line VL2 may transmit the initialization voltage Vint to the second initialization transistor T7.

A driving gate electrode G1 of the driving transistor T1 is connected to a lower electrode CE1 of the storage capacitor Cst, a driving source electrode S1 of the driving transistor T1 is connected to a lower driving voltage line PL via the operation control transistor T5, and a driving drain electrode D1 of the driving transistor T1 is electrically connected to a pixel electrode of a main organic light-emitting diode OLED via the emission control transistor T6. The driving transistor T1 receives the data signal Dm according to a switching operation of a switching transistor T2 and supplies a driving current IOLED to the organic light-emitting diode OLED.

A switching gate electrode G2 of the switching transistor T2 is connected to the scan line SL, a switching source electrode S2 of the switching transistor T2 is connected to the data line DL, and a switching drain electrode D2 of the switching transistor T2 is connected to the driving source electrode S1 of the driving transistor T1 and, via the operation control transistor T5, to the lower driving voltage line PL. The switching transistor T2 is turned on according to the scan signal Sn received through the scan line SL and performs a switching operation to transmit the data signal Dm transmitted through the data line DL to the driving source electrode S1 of the driving transistor T1.

A compensation gate electrode G3 of a compensation transistor T3 is connected to the scan line SL, a compensation source electrode S3 of the compensation transistor T3 is connected to the driving drain electrode D1 of the driving transistor T1 and, via the emission control transistor T6, to a pixel electrode of the organic light-emitting device OLED, and a compensation drain electrode D3 of the compensation transistor T3 is connected to the lower electrode CE1 of the storage capacitor Cst, a first initialization drain electrode D4 of the first initialization transistor T4, and the driving gate electrode G1 of the driving transistor T1. The compensation transistor T3 is turned on according to the scan signal Sn received through the scan line SL and electrically connects the driving gate electrode G1 and the driving drain electrode D1 of the driving transistor T1, thereby diode-connecting the driving transistor T1.

A first initialization gate electrode G4 of the first initialization transistor T4 is connected to the previous scan line SL−1, a first initialization source electrode S4 of the first initialization transistor T4 is connected to the first initialization voltage line VL1, and a first initialization drain electrode D4 of the first initialization transistor T4 is connected to the lower electrode CE1 of the storage capacitor Cst, the compensation drain electrode D3 of the compensation transistor T3, and the driving gate electrode G1 of the driving transistor T1. The first initialization transistor T4 is turned on according to the previous scan signal Sn−1 received through the previous scan line SL−1 and performs an initialization operation of transmitting the initialization voltage Vint to the driving gate electrode G1 of the driving transistor T1 to initialize the voltage of the driving gate electrode G1 of the driving transistor T1.

An operation control gate electrode G5 of the operation control transistor T5 is connected to the emission control line EL, an operation control source electrode S5 of the operation control transistor T5 is connected to the lower driving voltage line PL, and an operation control drain electrode D5 of the operation control transistor T5 is connected to the driving source electrode S1 of the driving transistor T1 and the switching drain electrode D2 of the switching transistor T2.

An emission control gate electrode G6 of the emission control transistor T6 is connected to the emission control line EL, an emission control source electrode S6 of the emission control transistor T6 is connected to the driving drain electrode D1 of the driving transistor T1 and the compensation source electrode S3 of the compensation transistor T3, and an emission control drain electrode D6 of the emission control transistor T6 is electrically connected to a second initialization source electrode S7 of the second initialization transistor T7 and the pixel electrode of the organic light-emitting device OLED.

The operation control transistor T5 and the emission control transistor T6 are simultaneously turned on according to the emission control signal En received through the emission control line EL, such that the driving voltage ELVDD is transmitted to the organic light-emitting device OLED to allow the driving current IOLED to flow to the organic light-emitting device OLED.

A second initialization gate electrode G7 of the second initialization transistor T7 is connected to the subsequent scan line SL+1, the second initialization source electrode S7 of the second initialization transistor T7 is connected to the emission control drain electrode D6 of the emission control transistor T6 and the pixel electrode of the main organic light-emitting device OLED, and a second initialization drain electrode D7 of the second initialization transistor T7 is connected to the second initialization voltage line VL2.

The subsequent scan line SL+1 may receive a subsequent scan signal Sn+1 of a subsequent pixel in the y direction. The second initialization transistor T7 may be turned on according to the subsequent scan signal Sn+1 received through the subsequent scan line SL+1 and perform an operation of initializing the pixel electrode of the organic light-emitting device OLED.

An upper electrode CE2 of the storage capacitor Cst is connected to the driving voltage line PL, and a common electrode of the organic light-emitting device OLED is connected to the common voltage ELVSS. The organic light-emitting device OLED may display an image by emitting light by receiving the driving current IOLED from the driving transistor T1.

Although FIG. 4 shows that the compensation transistor T3 and the first initialization transistor T4 each have dual gate electrodes, the compensation transistor T3 and the first initialization transistor T4 may each have a single gate electrode.

Also, although FIG. 4 illustrates a structure for a pixel circuit PC, a plurality of pixels PX each having the pixel circuit PC may be arranged to form a plurality of rows, and the first initialization voltage line VL1, the previous scan line SL−1, the second initialization voltage line VL2, and the subsequent scan line SL+1 may be shared by pixels in a row.

In an embodiment, the first initialization voltage line VL1 and the previous scan line SL−1 may be electrically connected to a first initialization thin-film transistor T4 of another pixel circuit PC arranged in the second direction (y direction). Therefore, a previous scan signal Sn−1 applied to the previous scan line SL−1 may be a scan signal of the scan line of the other pixel circuit PC (i.e. a previous pixel circuit PC). Similarly, the second initialization voltage line VL2 and the subsequent scan line SL+1 may be electrically connected to a second initialization thin-film transistor T7 of another pixel circuit PC arranged in the second direction (y direction) to transmit the subsequent scan signal Sn+1 to the scan line of the other pixel circuit PC (i.e. a subsequent pixel circuit PC).

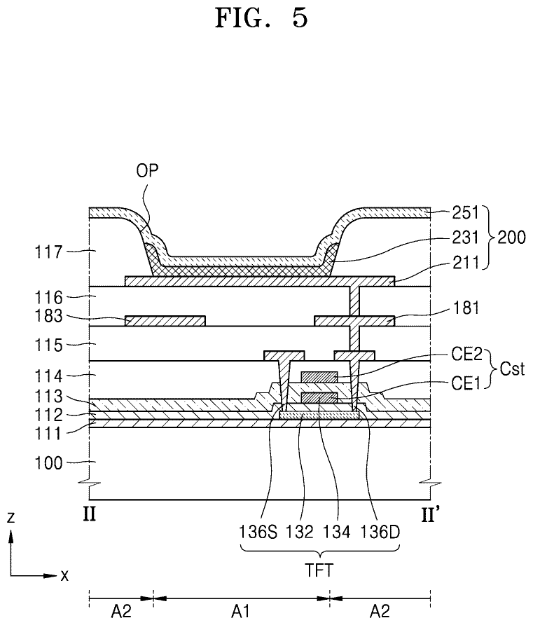

FIG. 5 is a schematic cross-sectional view of an example of a portion of a cross-section along a line II-II′ of FIG. 1.

Referring to FIG. 5, a buffer layer 111 may be formed on the substrate 100 to prevent impurities from penetrating into a semiconductor layer of a thin-film transistor.

The substrate 100 may include various materials such as glass, a metal, or a plastic. According to an embodiment, the substrate 100 may be a flexible substrate and, for example, may include a polymer resin such as polyethersulfone (PES), polyacrylate (PAR), polyetherimide (PEI), polyethylenenaphthalate (PEN), polyethylene terephthalate (PET), polyphenylenesulfide (PPS), polyimide (PI), polycarbonate (PC), or cellulose acetate propionate (CAP).

The buffer layer 111 may include an inorganic insulating material such as silicon nitride or silicon oxide, and may be a single layer or multiple layers.

A thin-film transistor TFT, a capacitor Cst, and an organic light-emitting diode 200 electrically connected to the thin-film transistor TFT may be arranged on the substrate 100. The organic light-emitting diode 200 being electrically connected to the thin-film transistor TFT may be understood as a pixel electrode 211 being electrically connected to the thin-film transistor TFT. The thin-film transistor TFT may be the driving transistor T1 of FIG. 4.

The thin-film transistor TFT may include a semiconductor layer 132, a gate electrode 134, a source electrode 136S, and a drain electrode 136D. The semiconductor layer 132 may include an oxide semiconductor material. The semiconductor layer 132 may include amorphous silicon, polycrystalline silicon, or an organic semiconductor material. The gate electrode 134 may be formed as a single layer or multiple layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), in consideration of adhesion to adjacent layers, surface flatness of stacked layers, and processability.

A gate insulation layer 112 including an inorganic material such as silicon oxide, silicon nitride, or silicon oxynitride may be provided between the semiconductor layer 132 and the gate electrode 134. A first interlayer insulation layer 113 and a second interlayer insulation layer 114 including an inorganic material such as silicon oxide, silicon nitride, or silicon oxynitride may be arranged between the gate electrode 134 and the source electrode 136S and the drain electrode 136D. The source electrode 136S and the drain electrode 136D may be electrically connected to the semiconductor layer 132 through contact holes respectively formed in the gate insulation layer 112, the first interlayer insulation layer 113, and the second interlayer insulation layer 114.

The source electrode 136S and the drain electrode 136D may be formed as a single layer or multiple layers using one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The capacitor Cst includes the lower electrode CE1 and the upper electrode CE2 that overlap each other with the first interlayer insulation layer 113 therebetween. The capacitor Cst may overlap the thin-film transistor TFT. FIG. 5 illustrates that the gate electrode 134 of the thin-film transistor TFT is the lower electrode CE1 of the capacitor Cst. According to another embodiment, the capacitor Cst may not overlap the thin-film transistor TFT. The capacitor Cst may be covered by the second interlayer insulation layer 114.

A pixel circuit including the thin-film transistor TFT and the capacitor Cst may be covered by a first insulation layer 115 and a second insulation layer 116. The first insulation layer 115 and the second insulation layer 116 are planarizing insulation layers and may be organic insulation layers. The first insulation layer 115 and the second insulation layer 116 may include organic insulators such as general-purpose polymers such as polymethylmethacrylate (PMMA) or polystylene (PS), polymer derivatives having phenolic groups, acrylic polymers, imide polymers, aryl ether polymers, amide polymers, fluorinated polymers, p-xylene polymers, vinyl alcohol polymers, and blends thereof. According to an embodiment, the first insulation layer 115 and the second insulation layer 116 may include polyimide.

A display element, e.g., the organic light-emitting diode 200, may be disposed on the second insulation layer 116. The organic light-emitting diode 200 may include the pixel electrode 211, an intermediate layer 231, and a counter electrode 251.

The pixel electrode 211 is disposed on the second insulation layer 116 and may be connected to the thin-film transistor TFT through a connection electrode 181 on the first insulation layer 115. Wires 183, such as the data line DL and the driving voltage line PL, may be arranged on the first insulation layer 115.

The pixel electrode 211 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the pixel electrode 211 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. According to another embodiment, the pixel electrode 211 may further include a film including ITO, IZO, ZnO or In₂O₃ above/below the above-stated reflective film.

A third insulation layer 117 may be disposed on the second insulation layer 116. The third insulation layer 117 may be a pixel defining film that defines a pixel by covering the edge portion of the pixel electrode 211 and having an opening OP that partially exposes the pixel electrode 211. The opening OP may correspond to an emission area A1. An area that does not correspond to the opening OP may be referred to as a non-emission area A2.

The third insulation layer 117 may prevent arcs or the like from occurring at the edge portion of the pixel electrode 211 by increasing the distance between the edge portion of the pixel electrode 211 and the counter electrode 251. The third insulation layer 117 may include an organic material such as polyimide (PI) or hexamethyldisiloxane (HMDSO).

The intermediate layer 231 includes an emission layer. The emission layer may include a polymer or a low-molecular organic material that emits light of a predetermined color. According to an embodiment, the intermediate layer 231 may include a first functional layer disposed below the emission layer or a second functional layer disposed above the emission layer. The first functional layer or the second functional layer may include a layer that is a single body across a plurality of pixel electrodes 211 or may include a layer patterned to correspond to each of the plurality of pixel electrodes 211.

The first functional layer may be a single layer or multiple layers. For example, when the first functional layer includes a polymer material, the first functional layer may be a hole transport layer (HTL) having a single layer structure and may include polyethylene dihydroxythiophene poly-(3,4)-ethylene-dihydroxy thiophene (PEDOT) or polyaniline (PANI). When the first functional layer includes a low-molecular material, the first functional layer may include a hole injection layer (HIL) and a HTL.

The second functional layer is not always provided. For example, when the first functional layer and the emission layer include polymer materials, the second functional layer may be formed to improve the characteristics of an organic light-emitting device. The second functional layer may be a single layer or multiple layers. The second functional layer may include an electron transport layer (ETL) or an electron injection layer (EIL).

The counter electrode 251 is disposed to face the pixel electrode 211 with the intermediate layer 231 therebetween. The counter electrode 251 may include a conductive material with a low work function. For example, the counter electrode 251 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the counter electrode 251 may further include a layer including ITO, IZO, ZnO, or In₂O₃ on the (semi) transparent layer including the above-stated material.

The counter electrode 251 may be disposed on the intermediate layer 231 and the third insulation layer 117. The counter electrode 251 may be integrated with a plurality of organic light-emitting diodes 200 in the display area DA and may face the plurality of pixel electrodes 211.

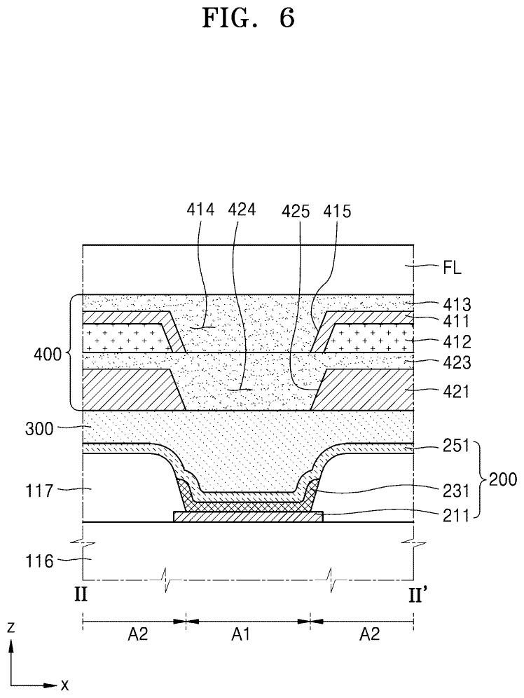

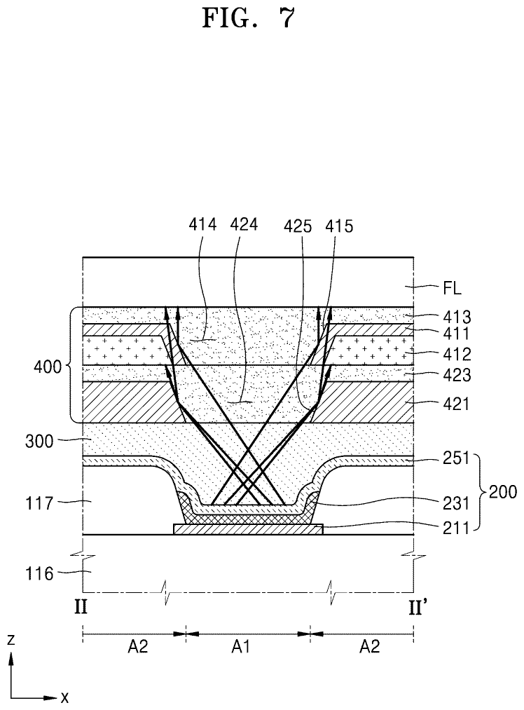

FIG. 6 is a schematic cross-sectional view of an example of a portion of a cross-section along the line II-II′ of FIG. 1, and FIG. 7 is a schematic cross-sectional view of an example of a portion of a cross-section along the line II-II′ of FIG. 1.

The display device 1 may be divided into the emission area A1 and the non-emission area A2. The emission area A1 may correspond to the opening OP that exposes a portion of the pixel electrode 211 in the third insulation layer 117. In more detail, the emission area A1 may be an area corresponding to the intermediate layer 231 of the organic light-emitting diode 200. In other words, the intermediate layer 231 may overlap the emission area A1. Light may be emitted from the emission area A1.

An area that does not correspond to the opening OP (particularly, an area that does not correspond to the intermediate layer 231) may be referred to as the non-emission area A2. The non-emission area A2 may be adjacent to the emission area A1.

A thin-film encapsulation layer may be disposed as the encapsulation member 300 on the counter electrode 251. The thin-film encapsulation layer protects the organic light-emitting diode 200 from moisture or oxygen from the outside. The thin-film encapsulation layer may have a multi-layered structure.

The functional layer FL such as the refractive layer 400, a polarization layer, a window, etc. may be disposed on the organic light-emitting diode 200 (e.g., on the encapsulation member 300).

The refractive layer 400 may control the path of light emitted from the emission layer of the organic light-emitting diode 200. The refractive layer 400 may change the path of light emitted from the emission layer of the organic light-emitting diode 200, which propagates laterally (e.g., in a direction other than the z direction), such that the light propagates approximately in the z direction, which is the forward direction.

People want to prevent information from being shared when they are watching screen images in public places. In other words, a special display device whose brightness is reduced beyond a certain viewing angle is desirable. A separate film may be applied to reduce brightness beyond a particular viewing angle or the viewing angle may be adjusted by providing a light-blocking member or the like. However, such techniques can increase the thickness of a display device or reduce brightness in the forward direction.

Embodiments of the present disclosure provide a display device in which a topmost refractive pattern covers a light-blocking pattern avoiding a significant increase in the thickness of the display device, increasing brightness in the forward direction, and reducing brightness at a certain angle (or greater) from normal to ensure privacy.

Referring to FIG. 6, the refractive layer 400 may be disposed between the encapsulation member 300 and the functional layer FL. The refractive layer 400 may include a first refractive pattern 411 and a second refractive pattern 421 disposed to overlap the first refractive pattern 411.

The first refractive pattern 411 may be disposed between the second refractive pattern 421 and the functional layer FL. The first refractive pattern 411 may be disposed to overlap the second refractive pattern 421 in the z direction. The first refractive pattern 411 may focus light travelling outward at a high angle in the forward direction.

The first refractive pattern 411 may not overlap the emission area A1 in the z direction. In other words, the first refractive pattern 411 may overlap the non-emission area A2 in the z direction.

The first refractive pattern 411 may be disposed to cover a first light-blocking pattern 412. In other words, the width of the first refractive pattern 411 between adjacent pixels may be greater than the width of the first light-blocking pattern 412 between adjacent pixels. The first light-blocking pattern 412 may be disposed on a second planarizing layer 423, and the first refractive pattern 411 may be disposed on the first light-blocking pattern 412 to cover the first light-blocking pattern 412. An area of the first refractive pattern 411 may contact the second planarizing layer 423.

The first light-blocking pattern 412 may block light. In detail, the first light-blocking pattern 412 may block light emitted at a high viewing angle. For example, the first light-blocking pattern 412 may include chromium (Cr), molybdenum (Mo), chromium oxide (CrOx), molybdenum oxide (MoOx), carbon pigment, black resin, etc.

A first planarizing layer 413 covers the first refractive pattern 411 and may be disposed on the second planarizing layer 423. According to an embodiment, the first planarizing layer 413 may have a flat top surface and include an organic material. The first planarizing layer 413 and the first refractive pattern 411 may have different refractive indices. The first refractive pattern 411 may include an organic material different from that constituting the first planarizing layer 413. According to an embodiment, the refractive index of the first planarizing layer 413 may be higher than the refractive index of the first refractive pattern 411. Therefore, light reaching a first reflective side surface 415 of the first refractive pattern 411 in the first planarizing layer 413 may be totally reflected, and light emitted through side surfaces may be directed in the forward direction, thereby including the brightness in the forward direction.

The first refractive pattern 411 may include a first penetration area 414 through which at least some of light emitted from the organic light-emitting diode 200 passes and the first reflective side surface 415 that reflects at least some of the light emitted by the organic light-emitting diode.

The first penetration area 414 may overlap the emission area A1. The first reflective side surface 415 may include an inclined surface. According to an embodiment, the angle between the inclined surface and the second planarizing layer 423 may be 45° or greater and 90° or less. According to another embodiment, the angle between the inclined surface and the second planarizing layer 423 may be 60° or greater and 70° or less.

The second refractive pattern 421 may be disposed between the first refractive pattern 411 and the encapsulation member 300. The second refractive pattern 421 may be disposed to overlap the first refractive pattern 411 in the z direction. According to an embodiment, the width of the second refractive pattern 421 between adjacent pixels may be identical to the width of the first refractive pattern 411 between the adjacent pixels.

The second refractive pattern 421 may focus light travelling outward at a high angle in the forward direction. In other words, by overlapping and stacking the first refractive pattern 411 on the second refractive pattern 421, light travelling outward at a high angle is focused in the forward direction, and thus the brightness in the forward direction may increase and the brightness in lateral directions may decrease. Also, by overlapping and stacking the first refractive pattern 411 on the second refractive pattern 421, light emitted at an angle greater than or equal to a particular angle is blocked by the first light-blocking pattern 412, and thus the light-blocking pattern may be omitted in the second refractive pattern 421. Therefore, the thickness of the display device 1 may be reduced. However, according to an embodiment, the display device 1 may further include a second light-blocking pattern covered by the second refractive pattern 421.

The second refractive pattern 421 may not overlap the emission area A1 in the z direction. In other words, the second refractive pattern 421 may overlap the non-emission area A2 in the z direction.

The second planarizing layer 423 may be disposed on the second refractive pattern 421, thereby arranging the first refractive pattern 411 and the second refractive pattern 421 to be spaced apart from each other. The second planarizing layer 423 covers the second refractive pattern 421 and may be disposed on the encapsulation member 300. According to an embodiment, the second planarizing layer 423 may have a flat top surface, and the first refractive pattern 411 may be disposed thereon.

The second planarizing layer 423 may include an organic material. The second planarizing layer 423 and the second refractive pattern 421 may have different refractive indices. The second refractive pattern 421 may include an organic material different from that constituting the second planarizing layer 423. According to an embodiment, the refractive index of the second planarizing layer 423 may be higher than the refractive index of the second refractive pattern 421. Therefore, light reaching a second reflective side surface 425 of the second refractive pattern 421 in the second planarizing layer 423 may be totally reflected, and light emitted through side surfaces may be directed in the forward direction, thereby increasing the brightness in the forward direction.

Also, according to an embodiment, the second planarizing layer 423 may include the same material as the first planarizing layer 413, and the second refractive pattern 421 may include the same material as the first refractive pattern 411.

The second refractive pattern 421 may include a second penetration area 424 through which at least some light emitted from the organic light-emitting diode 200 passes and the second reflective side surface 425 that reflects at least some of the light emitted from the organic light-emitting diode 200. In other words, a first portion of light emitted from the organic light-emitting diode 200 may pass through the second penetration area and a second portion of light may reflect from the second reflective side surface 425. The first and second portions of light may be referred to as transmitted light. Further, a first portion of the transmitted light may pass through the first penetration area 414 of the first refractive pattern 411 and a second portion of the transmitted light may reflect from the first reflective side surface 415 of the first refractive pattern 411.

The second penetration area 424 may overlap the emission area A1. The second reflective side surface 425 may include an inclined surface. According to an embodiment, the angle between the inclined surface and the encapsulation member 300 may be 45° or greater and 90° or less. According to another embodiment, the angle between the inclined surface and the encapsulation member 300 may be 60° or greater and 70° or less.

The first penetration area 414 and the second penetration area 424 may overlap each other in the z direction. According to an embodiment, the width of the first penetration area 414 and the width of the second penetration area 424 may be identical to each other.

Referring to FIG. 7, some light emitted from the organic light-emitting diode 200 may pass through the refractive layer 400 and the functional layer FL. However, some of the light may be blocked by the first light-blocking pattern 412.

According to an embodiment, light emitted from an organic light-emitting diode 200 may pass through the functional layer FL after being reflected by the first reflective side surface 415 of the first refractive pattern 411. According to another embodiment, light emitted from the organic light-emitting diode 200 may be blocked by the first light-blocking pattern 412 after being reflected by the second reflective side surface 425 of the second refractive pattern 421 or may pass through the functional layer FL after being refracted by the first refractive pattern 411.

By arranging a light-blocking pattern only on the topmost refractive pattern (that is, by disposing the first light-blocking pattern 412 only on the first refractive pattern 411 and not disposing a light-blocking pattern on the second refractive pattern 421), the brightness loss may be reduced, the brightness in the forward direction may be improved, and the brightness at sides of high viewing angles may be reduced.

If a light-blocking pattern is disposed for each refractive pattern, the overall thickness and the size of the refractive layer 400 increases, thereby reducing an open area through which light may pass. In other words, by covering a light-blocking pattern with a refractive pattern, the brightness loss due to a plurality of stacked light-blocking patterns may be reduced. However, disposing a light-blocking pattern only under the topmost refractive pattern may be better for preventing the brightness loss in the forward direction.

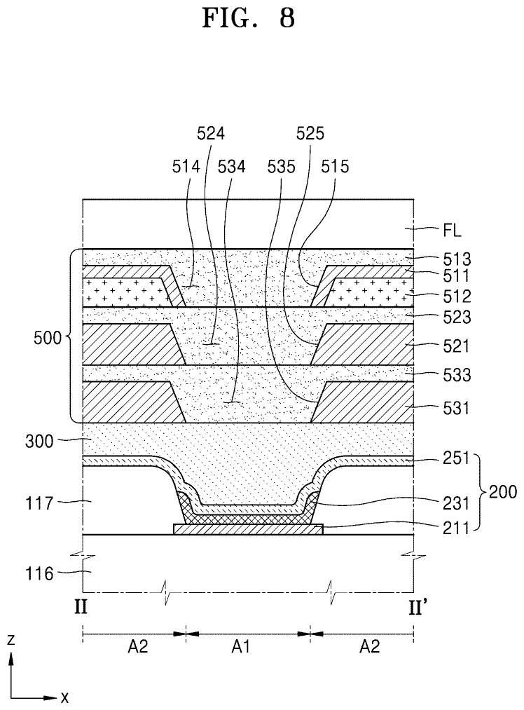

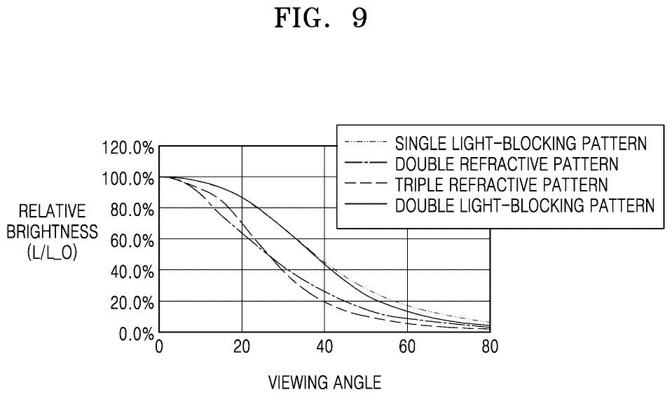

FIG. 8 is a schematic cross-sectional view of another example of a portion of the cross-section along the line II-II′ of FIG. 1, and FIG. 9 is a graph showing relative brightness according to viewing angles.

The display device 1 according to an embodiment may include a refractive layer 500 including a first refractive pattern 511, a second refractive pattern 521, and a third refractive pattern 531.

The first refractive pattern 511, the second refractive pattern 521, a first light-blocking pattern 512, a first planarizing layer 513, a second planarizing layer 523, a first penetration area 514, a second penetration area 524, a first reflective side surface 515, and a second reflective side surface 525 of the refractive layer 500 may correspond to the first refractive pattern 411, the second refractive pattern 421, the first light-blocking pattern 412, the first planarizing layer 413, the second planarizing layer 423, the first penetration area 414, the second penetration area 424, the first reflective side surface 415, and the second reflective side surface 425, respectively.

However, the refractive layer 500 may further include the third refractive pattern 531 and a third planarizing layer 533 covering the third refractive pattern 531 between the second refractive pattern 521 and the encapsulation member 300.

The third refractive pattern 531 may be disposed between the second refractive pattern 521 and the encapsulation member 300. The third refractive pattern 531 may be disposed to overlap the first refractive pattern 511 and the second refractive pattern 521 in the z direction. According to an embodiment, the width of the third refractive pattern 531 between adjacent pixels may be identical to each of the width of the second refractive pattern 521 and the width of the first refractive pattern 511 between the adjacent pixels.

The third refractive pattern 531 may focus light travelling outward at a high angle in the forward direction. In other words, by overlapping and stacking the second refractive pattern 521 on the third refractive pattern 531 and the first refractive pattern 511 on the second refractive pattern 521, light travelling outward at a high angle is focused in the forward direction, and thus the brightness in the forward direction may increase and the brightness in lateral directions may decrease.

Also, since light emitted beyond a certain angle is blocked by the first light-blocking pattern 512, a blocking pattern may be omitted in the third refractive pattern 531, and thus the thickness of the display device 1 may be reduced. However, according to an embodiment, the display device 1 may further include a third light-blocking pattern covered by the third refractive pattern 531 or a second light-blocking pattern covered by the second refractive pattern 521.

The third refractive pattern 531 may not overlap the emission area A1 in the z direction. In other words, the third refractive pattern 531 may overlap the non-emission area A2 in the z direction.

The third planarizing layer 533 covers the third refractive pattern 531 and may be disposed on the encapsulation member 300. The third planarizing layer 533 may be disposed on the third refractive pattern 531, such that the third refractive pattern 531 and the second refractive pattern 521 are spaced apart from each other. According to an embodiment, the third planarizing layer 533 may have a flat top surface, and the second refractive pattern 521 may be disposed thereon.

The third planarizing layer 533 may include an organic material. The third refractive pattern 531 may include an organic material different from that constituting the third planarizing layer 533. The third planarizing layer 533 and the third refractive pattern 531 may have different refractive indices. According to an embodiment, the refractive index of the third planarizing layer 533 may be higher than the refractive index of the third refractive pattern 531. Therefore, light reaching a third reflective side surface 535 of the third refractive pattern 531 in the third planarizing layer 533 may be totally reflected, and light emitted through side surfaces may be directed in the forward direction, thereby including the brightness in the forward direction.

Also, according to an embodiment, the third planarizing layer 533 may include the same material as the second planarizing layer 523 and the first planarizing layer 513, and the third refractive pattern 531 may include the same material as the second refractive pattern 521 and the first refractive pattern 511.

The third refractive pattern 531 may include a third penetration area 534 through which at least some light emitted from the organic light-emitting diode 200 passes and the third reflective side surface 535 that reflects at least some of the light emitted from the organic light-emitting diode 200.

The third penetration area 534 may overlap the emission area A1. The third reflective side surface 535 may include an inclined surface. According to an embodiment, the angle between the inclined surface and the encapsulation member 300 may be 45° or greater and 90° or less. According to another embodiment, the angle between the inclined surface and the encapsulation member 300 may be 60° or greater and 70° or less.

The third penetration area 534 may overlap the first penetration area 514 and the second penetration area 524 in the z direction. According to an embodiment, the width of the third penetration area 534 may be identical to each of the width of the first penetration area 514 and the width of the second penetration area 524.

FIG. 9 is a graph showing relative brightness according to viewing angles of each of a single light-blocking pattern having only one light-blocking pattern without a refractive pattern, a double refractive pattern having the first light-blocking pattern 412 disposed only on the first refractive pattern 411, a triple refractive pattern having the first light-blocking pattern 512 disposed only on the first refractive pattern 511, and a double light-blocking pattern having only light-blocking patterns double-stacked without a refractive pattern. Hereinafter, results of evaluating the wide angle display (WAD) characteristics for refractive layers according to various embodiments are reviewed.

The graph shows the brightness in the forward direction as the viewing angle becomes smaller and shows the brightness in lateral directions as the viewing angle becomes greater. When viewing a screen image in a public place, to prevent information from being shared by other people, the brightness in lateral directions should be low and the brightness in the forward direction should be high for high visibility and high light efficiency.

A single light-blocking pattern with only one light-blocking pattern without a refractive pattern exhibits higher relative brightness at high viewing angles than a double light-blocking pattern, a double refractive pattern, and a triple refractive pattern, and thus it is difficult to maintain privacy.

A double light-blocking pattern is a pattern in which only light-blocking patterns are double-stacked without a refractive pattern and the distance between light-blocking patterns is constant. Since reduction of the relative brightness at high viewing angles is very small as compared to a double refractive pattern and a triple refractive pattern, it is difficult to maintain privacy.

The double refractive pattern in which the first light-blocking pattern 412 is disposed only on the first refractive pattern 411 may protect privacy, because the relative brightness is lower at high viewing angles as compared to the double light-blocking pattern. However, the relative brightness in the forward direction is lower than that of the triple refractive pattern, and thus the light efficiency of the double refractive pattern may be relatively low. However, since the double refractive pattern does not include a third refractive pattern or a third planarizing layer like the triple refractive pattern, a display device thinner and lighter than the triple refractive pattern may be manufactured.

The triple refractive pattern in which the first light-blocking pattern 512 is disposed only on the first refractive pattern 511 and the third refractive pattern 531 is further included between the second refractive pattern 521 and the encapsulation member 300 exhibits the lowest brightness at high viewing angles, thereby providing the best privacy protection. Also, the triple refractive pattern exhibits higher brightness in the forward direction than the double refractive pattern, thus exhibiting good light efficiency.

In other words, both the double refractive pattern and the triple refractive pattern, in which only the first refractive pattern 411 or 511, which is the topmost layer, covers the first light-blocking pattern 412 or 512), exhibit lower brightness at high viewing angles as compared to the double light-blocking pattern in which light-blocking patterns are double-stacked without a refractive pattern and reduce the brightness beyond a particular angle, thereby preventing information from being shared by other people when viewing a screen image for privacy protection. When a plurality of refractive patterns are stacked, the brightness at high viewing angles may be reduced without increasing the thickness of a display device.

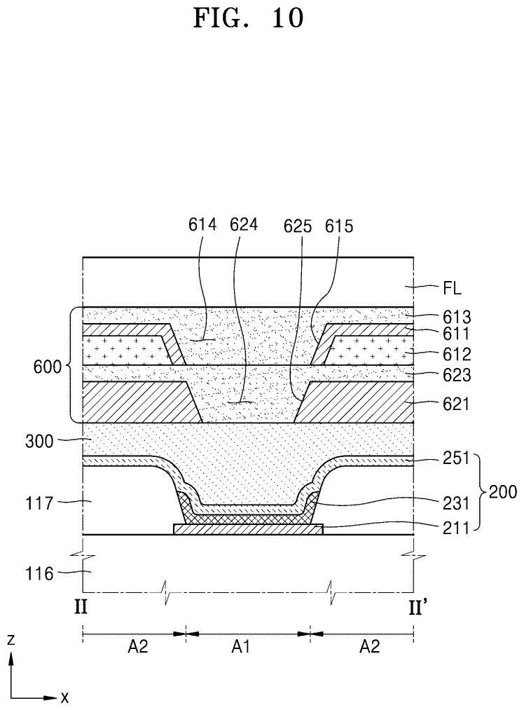

FIG. 10 is a schematic cross-sectional view of another example of a portion of a cross-section along the line II-II′ of FIG. 1.

The display device 1 according to another embodiment may include a refractive layer 600 including a first refractive pattern 611 and a second refractive pattern 621 having a width different from that of the first refractive pattern 611.

Referring to FIG. 10, the refractive layer 600 may be disposed between the encapsulation member 300 and the functional layer FL. The refractive layer 600 may include the first refractive pattern 611 and the second refractive pattern 621 disposed to overlap the first refractive pattern 611.

The first refractive pattern 611 may be disposed between the second refractive pattern 621 and the functional layer FL. The first refractive pattern 611 may be disposed to overlap the second refractive pattern 621 in the z direction. The first refractive pattern 611 may focus light travelling outward at a high angle in the forward direction.

The first refractive pattern 611 may not overlap the emission area A1 in the z direction. In other words, the first refractive pattern 611 may overlap the non-emission area A2 in the z direction.

The first refractive pattern 611 may be disposed to cover a first light-blocking pattern 612. In other words, the width of the first refractive pattern 611 may be greater than the width of the first light-blocking pattern 612. The first light-blocking pattern 612 may be disposed on a second planarizing layer 623, and the first refractive pattern 611 may be disposed on the first light-blocking pattern 612 to cover the first light-blocking pattern 612. In other words, one area of the first refractive pattern 611 may contact the second planarizing layer 623.

The first light-blocking pattern 612 may block light. In detail, the first light-blocking pattern 612 may block light emitted at a high viewing angle. For example, the first light-blocking pattern 612 may include chromium (Cr), molybdenum (Mo), chromium oxide (CrOx), molybdenum oxide (MoOx), carbon pigment, black resin, etc.

A first planarizing layer 613 covers the first refractive pattern 611 and may be disposed on the second planarizing layer 623. According to an embodiment, the first planarizing layer 613 may have a flat top surface and include an organic material. The first refractive pattern 611 may include an organic material different from that constituting the first planarizing layer 613. The first planarizing layer 613 and the first refractive pattern 611 may have different refractive indices. According to an embodiment, the refractive index of the first planarizing layer 613 may be higher than the refractive index of the first refractive pattern 611. Therefore, light reaching a first reflective side surface 615 of the first refractive pattern 611 in the first planarizing layer 613 may be totally reflected, and light emitted through side surfaces may be directed in the forward direction, thereby including the brightness in the forward direction.

The first refractive pattern 611 may include a first penetration area 614 through which at least some light emitted from the organic light-emitting diode 200 pass and a first reflective side surface 615 that reflects at least some of the light emitted from the organic light-emitting diode 200.

The first penetration area 614 may overlap the emission area A1. The first reflective side surface 615 may include an inclined surface. According to an embodiment, the angle between the inclined surface and the second planarizing layer 623 may be 45° or greater and 90° or less. According to another embodiment, the angle between the inclined surface and the second planarizing layer 623 may be 60° or greater and 70° or less.

The second refractive pattern 621 may be disposed between the first refractive pattern 611 and the encapsulation member 300. The second refractive pattern 621 may be disposed to overlap the first refractive pattern 611 in the z direction.

The second refractive pattern 621 may focus light travelling outward at a high angle in the forward direction. In other words, by overlapping and stacking the first refractive pattern 611 on the second refractive pattern 621, light travelling outward at a high angle is continuously focused in the forward direction, and thus the brightness in the forward direction may increase and the brightness of side surfaces may decrease.

The width of the second refractive pattern 621 between adjacent pixels may be greater than the width of the first refractive pattern 611 between the adjacent pixels. In other words, when the distance in the x direction from the center of the emission area A1 is measured, the distance from the center of the emission area A1 to the first refractive pattern 611 may be greater than the distance from the center of the emission area A1 to the second refractive pattern 621. Therefore, the amount of light emitted in the forward direction may increase.

By overlapping and stacking the first refractive pattern 611 on the second refractive pattern 621, light emitted at an angle greater than or equal to a particular angle is blocked by the first light-blocking pattern 612, and thus the light-blocking pattern may be omitted in the second refractive pattern 621. Therefore, the thickness of the display device 1 may be reduced. However, according to an optional embodiment, the display device 1 may further include a second light-blocking pattern covered by the second refractive pattern 621.

The second refractive pattern 621 may not overlap the emission area A1 in the z direction. In other words, the second refractive pattern 621 may overlap the non-emission area A2 in the z direction.

The second planarizing layer 623 may be disposed on the second refractive pattern 621, thereby arranging the first refractive pattern 611 and the second refractive pattern 621 to be spaced apart from each other. The second planarizing layer 623 covers the second refractive pattern 621 and may be disposed on the encapsulation member 300. According to an embodiment, the second planarizing layer 623 may have a flat top surface, and the first refractive pattern 611 may be disposed thereon.

The second planarizing layer 623 may include an organic material. The second refractive pattern 621 may include an organic material different from that constituting the second planarizing layer 623. The second planarizing layer 623 and the second refractive pattern 621 may have different refractive indices. According to an embodiment, the refractive index of the second planarizing layer 623 may be higher than the refractive index of the second refractive pattern 621. Therefore, light reaching a second reflective side surface 625 of the second refractive pattern 621 in the second planarizing layer 623 may be totally reflected, and light emitted through side surfaces may be directed in the forward direction, thereby including the brightness in the forward direction.

Also, according to an embodiment, the second planarizing layer 623 may include the same material as the first planarizing layer 613, and the second refractive pattern 621 may include the same material as the first refractive pattern 611.

The second refractive pattern 621 may include a second penetration area 624 through which at least some light emitted from the organic light-emitting diode 200 passes and the second reflective side surface 625 that reflects at least some of the light emitted from the organic light-emitting diode 200.

The second penetration area 624 may overlap the emission area A1. The second reflective side surface 625 may include an inclined surface. According to an embodiment, the angle between the inclined surface and the encapsulation member 300 may be 45° or greater and 90° or less. According to another embodiment, the angle between the inclined surface and the encapsulation member 300 may be 60° or greater and 70° or less.

The first penetration area 614 and the second penetration area 624 may overlap each other in the z direction. However, the width of the first penetration area 614 may be greater than the width of the second penetration area 624, and thus the brightness in the forward direction may be increased.

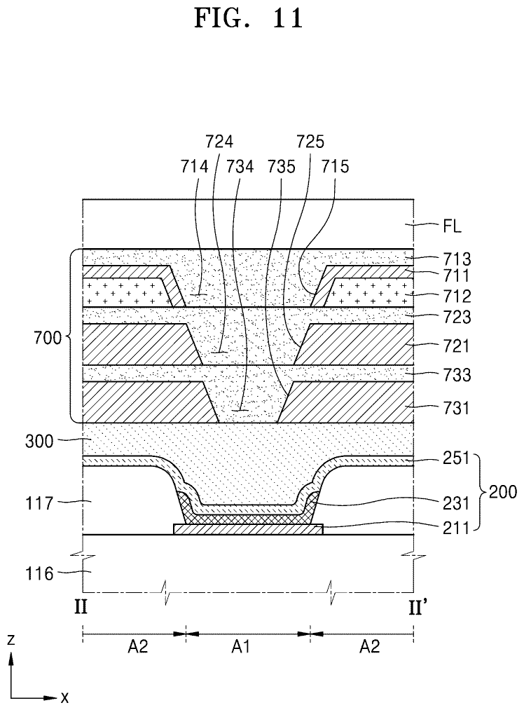

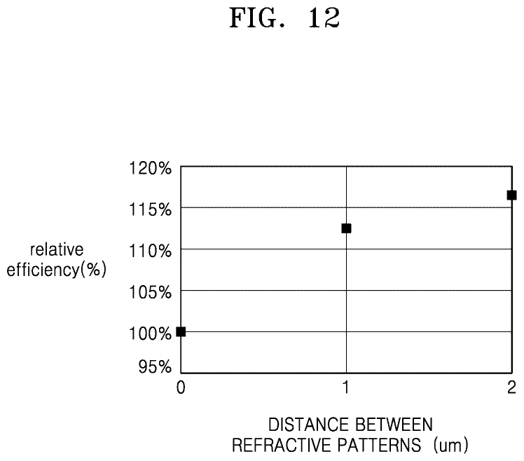

FIG. 11 is a schematic cross-sectional view of another example of a portion of the cross-section along the line II-II′ of FIG. 1, and FIG. 12 is a graph showing relative efficiency according to distances between refractive patterns.

The display device 1 according to another embodiment may include a refractive layer 700 including a first refractive pattern 711, a second refractive pattern 721, and a third refractive pattern 731.

The first refractive pattern 711, the second refractive pattern 721, a first light-blocking pattern 712, a first planarizing layer 713, a second planarizing layer 723, a first penetration area 714, a second penetration area 724, a first reflective side surface 715, and a second reflective side surface 725 of the refractive layer 700 may correspond to the first refractive pattern 611, the second refractive pattern 621, the first light-blocking pattern 612, the first planarizing layer 613, the second planarizing layer 623, the first penetration area 614, the second penetration area 624, the first reflective side surface 615, and the second reflective side surface 625, respectively.

However, the refractive layer 700 may further include the third refractive pattern 731 and a third planarizing layer 733 covering the third refractive pattern 731 between the second refractive pattern 721 and the encapsulation member 300.

The third refractive pattern 731 may be disposed between the second refractive pattern 721 and the encapsulation member 300. The third refractive pattern 731 may be disposed to overlap the first refractive pattern 711 and the second refractive pattern 721 in the z direction.

The width of the third refractive pattern 731 between adjacent pixels may be greater than each of the width of the second refractive pattern 721 and the width of the first refractive pattern 711 between the adjacent pixels. In other word, when the distance in the x direction from the center of the emission area A1 is measured, the distance from the center of the emission area A1 to the third refractive pattern 731 may be smaller than the distance from the center of the emission area A1 to the second refractive pattern 721 and the distance from the center of the emission area A1 to the first refractive pattern 711. Therefore, the amount of light emitted in the forward direction may increase.

The third refractive pattern 731 may focus light travelling outward at a high angle in the forward direction. In other words, by overlapping and stacking the second refractive pattern 721 on the third refractive pattern 731 and the first refractive pattern 711 on the second refractive pattern 721, light travelling outward at a high angle is continuously focused in the forward direction, and thus the brightness in the forward direction may increase and the brightness in lateral directions may decrease.

Also, since light emitted beyond a certain angle is blocked by the first light-blocking pattern 712, a blocking pattern may be omitted in the third refractive pattern 731, and thus the thickness of the display device 1 may be reduced. However, according to an optional embodiment, the display device 1 may further include a third light-blocking pattern covered by the third refractive pattern 731 or a second light-blocking pattern covered by the second refractive pattern 721.

The third refractive pattern 731 may not overlap the emission area A1 in the z direction. In other words, the third refractive pattern 731 may overlap the non-emission area A2 in the z direction.

The third planarizing layer 733 covers the third refractive pattern 731 and may be disposed on the encapsulation member 300. The third planarizing layer 733 may be disposed on the third refractive pattern 731, such that the third refractive pattern 731 and the second refractive pattern 721 are spaced apart from each other. According to an embodiment, the third planarizing layer 733 may have a flat top surface, and the second refractive pattern 721 may be disposed thereon.

The third planarizing layer 733 may include an organic material. The third refractive pattern 731 may include an organic material different from that constituting the third planarizing layer 733. The third planarizing layer 733 and the third refractive pattern 731 may have different refractive indices. According to an embodiment, the refractive index of the third planarizing layer 733 may be higher than the refractive index of the third refractive pattern 731. Therefore, light reaching a third reflective side surface 735 of the third refractive pattern 731 in the third planarizing layer 733 may be totally reflected, and light emitted through side surfaces may be directed in the forward direction, thereby including the brightness in the forward direction.

Also, according to an embodiment, the third planarizing layer 733 may include the same material as the second planarizing layer 723 and the first planarizing layer 713, and the third refractive pattern 731 may include the same material as the second refractive pattern 721 and the first refractive pattern 711.

The third refractive pattern 731 may include a third penetration area 734 through which at least some light emitted from the organic light-emitting diode 200 passes and the third reflective side surface 735 that reflects at least some of the light emitted from the organic light-emitting diode 200.

The third penetration area 734 may overlap the emission area A1. The third reflective side surface 735 may include an inclined surface. According to an embodiment, the angle between the inclined surface and the encapsulation member 300 may be 45° or greater and 90° or less. According to another embodiment, the angle between the inclined surface and the encapsulation member 300 may be 60° or greater and 70° or less.

The third penetration area 734 may overlap the first penetration area 714 and the second penetration area 724 in the z direction. However, the width of the third penetration area 734 is smaller than each of the width of the first penetration area 714 and the width of the second penetration area 724, and thus the brightness in the forward direction may be increased.

FIG. 12 is a graph showing relative efficiency for brightness in the forward direction according to differences between the distance from the center of the emission area A1 to the third refractive pattern (731 of FIG. 11) and the distance from the center of the emission area A1 to the first refractive pattern (711 of FIG. 11), when the distance in the x direction from the center of the emission area A1 is measured.

Referring to FIG. 12, when a case where the width of the third refractive pattern 731 is identical to the width of the first refractive pattern 711 (that is, when the width of the first penetration area 714 is identical to the width of the third penetration area 734) is set to correspond to 100% brightness in the forward direction, the relative efficiency is about 113% when the difference between the distance from the center of the emission area A1 to the third refractive pattern 731 and the distance from the center of the emission area A1 to the first refractive pattern 711 is 1 μm. The relative efficiency rises to about 116% when the difference between the distance from the center of the emission area A1 to the third refractive pattern 731 and the distance from the center of the emission area A1 to the first refractive pattern 711 is 2 μm.

In other words, when a plurality of refractive patterns are stacked in a refractive layer, distances in the x direction from the center of the emission area A1 to upper refractive patterns may increase to improve the brightness in the forward direction.

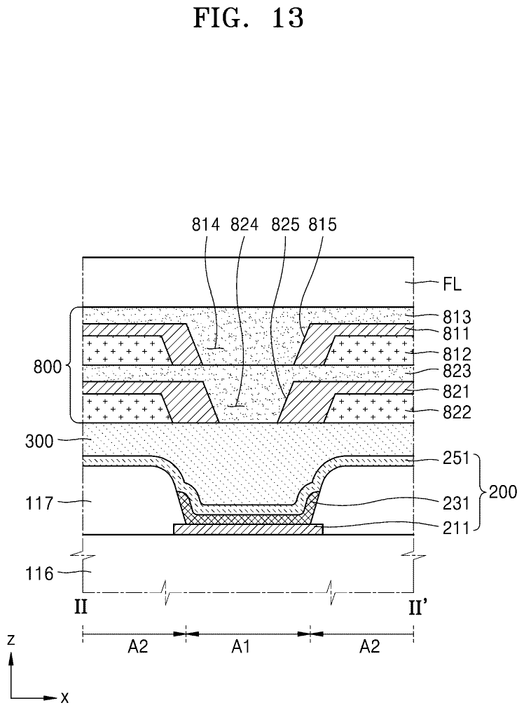

FIG. 13 is a schematic cross-sectional view of another example of a portion of a cross-section along the line II-II′ of FIG. 1.

The display device 1 according to another embodiment may include a refractive layer 800 including a first refractive pattern 811 and a second refractive pattern 821 having a width different from that of the first refractive pattern 611 and covering a second light-blocking pattern 822.

The first refractive pattern 811, the second refractive pattern 821, a first light-blocking pattern 812, a first planarizing layer 813, a second planarizing layer 823, a first penetration area 814, a second penetration area 824, a first reflective side surface 815, and a second reflective side surface 825 of the refractive layer 800 may correspond to the first refractive pattern 611, the second refractive pattern 621, the first light-blocking pattern 612, the first planarizing layer 613, the second planarizing layer 623, the first penetration area 614, the second penetration area 624, the first reflective side surface 615, and the second reflective side surface 625, respectively.

However, the refractive layer 800 may further include the second light-blocking pattern 822 covered by the second refractive pattern 821. To reduce the reflectivity in lateral directions, the second refractive pattern 821 may be disposed to cover the second light-blocking pattern 822. The width of the second refractive pattern 821 between adjacent pixels may be greater than the width of the second light-blocking pattern 822 between the adjacent pixels. The second light-blocking pattern 822 may be disposed on the encapsulation member 300, and the second refractive pattern 821 may be disposed on the second light-blocking pattern 822 to cover the second light-blocking pattern 822.

The second light-blocking pattern 822 may block light. In detail, the second light-blocking pattern 822 may block light emitted at a high viewing angle. For example, the second light-blocking pattern 822 may include chromium (Cr), molybdenum (Mo), chromium oxide (CrOx), molybdenum oxide (MoOx), carbon pigment, black resin, etc.

The first light-blocking pattern 812 and the second light-blocking pattern 822 may have the same width. In other words, when the distance in the x direction from the center of the emission area A1 is measured, the distance from the center of the emission area A1 to the first light-blocking pattern 812611 may be identical to the distance from the center of the emission area A1 to the second light-blocking pattern 822. Therefore, the loss of the light efficiency may be reduced.

The display device 1 according to an embodiment may be applied to various electronic devices 1000. An electronic device 1000 according to an embodiment may include the display device 1 described above, and may further include a module or device having additional functions, in addition to the display device 1.

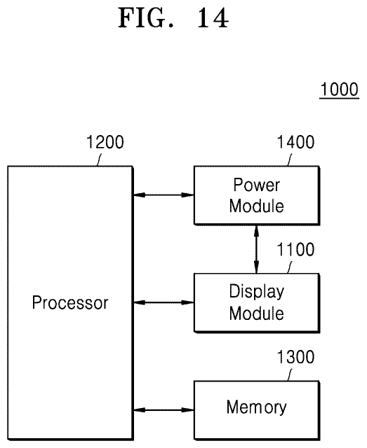

FIG. 14 is a block diagram of an electronic device according to an embodiment. Referring to FIG. 14, an electronic device 1000 according to an embodiment may include a display module 1100, a processor 1200, a memory 1300, and a power module 1400.

The processor 1200 may include at least one of a central processing unit (CPU), an application processor (AP), a graphics processing unit (GPU), a communication processor (CP), an image signal processor (ISP), or a controller.

The memory 1300 may store data information required for operation of the processor 1200 or the display module 1100. An image data signal or an input control signal may be transmitted to the display module 1100 in case that the processor 1200 executes an application stored in the memory 1300, and the display module 1100 may output image information through a display screen by processing the received signal.

The power module 1400 may include a power supply module, such as a power adapter or a battery device, and a power conversion module which converts power supplied by the power supply module to generate power required for the operation of the electronic device 1000.

At least one of respective components of the electronic device 1000 may be included in the display device 1 according to those embodiments described above. In some embodiments, some of the individual modules functionally included in a module may be included in a display device, while others may be provided separately from the display device. For example, the display device 1 may include the display module 1100, and the processor 1200, the memory 1300, and the power module 1400 may be provided in the form of other apparatuses in the electronic device 1000 other than the display device 1.

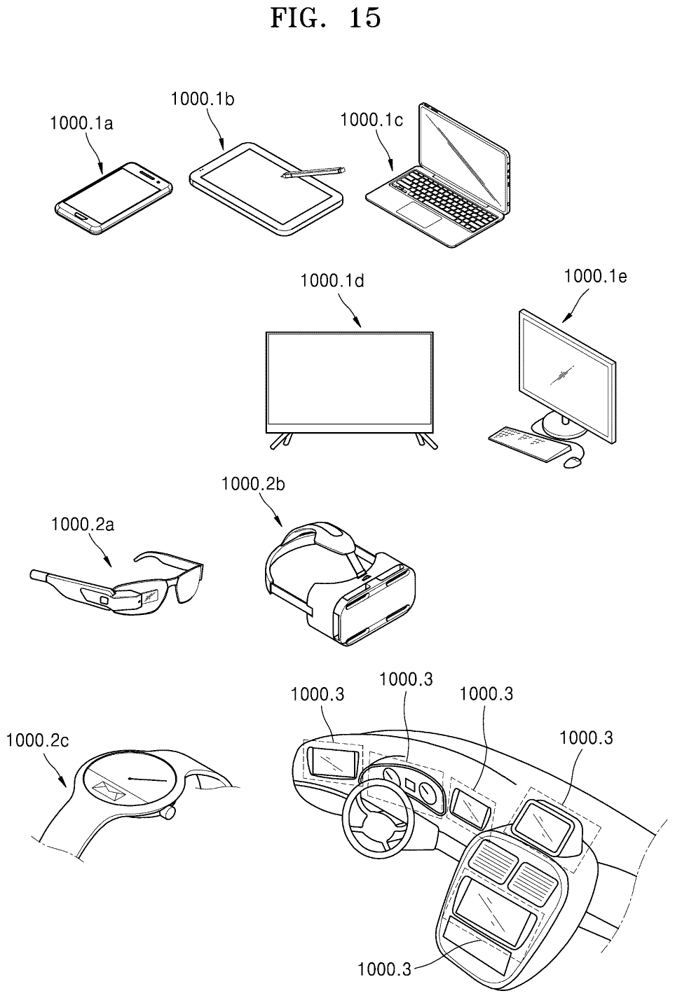

FIG. 15 illustrates schematic views of individual electronic devices according to various embodiments.

Referring to FIG. 15, various electronic devices according to embodiments, to which the display device 1 is applied, may include: an electronic device for displaying an image, such as a smart phone 1000.1a, a tablet PC 1000.1b, a laptop computer 1000.1c, a TV set 1000.1d, a desk monitor 1000.1e, and the like; a wearable electronic device including a display module, such as smart glasses 1000.2a, a head mounted display 1000.2b, a smart watch 1000.2c, and the like; and an electronic device 1000.3 for vehicles including a display module, such as a center information display (CID) arranged on an instrument panel, center fascia, or dashboard of a vehicle, a room mirror display, and the like.

Each of the embodiments described above may be implemented independently, but it goes without saying that the structure of each embodiment may be applied in combination to other embodiments.

While the disclosure has been described with reference to embodiments, it is to be understood that the disclosure is not limited to the disclosed embodiments, but, on the contrary, is intended to cover various modifications and equivalent arrangements included within the spirit and scope of the appended claims. Accordingly, the true scope of protection of the disclosure should be determined by the technical idea of the appended claims.

The specific implementations described in the embodiments are merely examples and do not limit the scope of the embodiments in any way. Also, if there is no specific mention such as “essential” or “important,” it may not be a component absolutely necessary for the application of the disclosure.

The use of the term “said” and similar referential terms in the specification of embodiments (especially in the claims) may refer to both the singular and the plural. Also, when a range is described in an embodiment, it is considered that the disclosure includes an individual value that falls within the range (unless otherwise stated), and it is equivalent to the description of each individual value that constitutes the range in the detailed description. Finally, unless there is an explicit description of the order or sequence of steps constituting a method according to the embodiment, the steps may be performed in any suitable order. Embodiments are not necessarily limited to the order in which the above steps are described. Any use of examples or exemplary terms in the embodiments is merely intended to describe the embodiments in detail and is not intended to limit the scope of the embodiments, unless otherwise defined by the claims. Furthermore, one of ordinary skill in the art will appreciate that various modifications, combinations and variations may be made according to design conditions and factors within the scope of the appended claims or their equivalents.

According to embodiments of the disclosure, by controlling the viewing angle using a refractive pattern and a light-blocking pattern, it is possible to prevent or reduce information provided by a display device from being shared with others.

However, the effects obtainable through the disclosure are not limited to the effects described above, and other technical effects not mentioned will be clearly understood by one of ordinary skill in the art from the description of the disclosure described below.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims.

What is claimed is:

1. A display device comprising:
a substrate;
a pixel layer disposed on the substrate and comprising a pixel, the pixel comprising an organic light-emitting diode;
an encapsulation member that seals the pixel layer; and
a refractive layer disposed on the encapsulation member and comprising a second refractive pattern and a first refractive pattern,
wherein the second refractive pattern comprises a second penetration area through which a first portion of light emitted from the organic light-emitting diode passes and a second reflective side surface that reflects a second portion of the light emitted from the organic light-emitting diode, the first and second portions of the light emitted from the organic light emitting diode forming transmitted light; and
the first refractive pattern is disposed to overlap the second refractive pattern and comprises a first penetration area through which a first portion of the transmitted light passes and a first reflective side surface that reflects a second portion of the transmitted light.

2. The display device of claim 1,
wherein the second refractive pattern is disposed between the encapsulation member and the first refractive pattern.

3. The display device of claim 1,
wherein the second refractive pattern is disposed to be spaced apart from the first refractive pattern.

4. The display device of claim 1,
further comprising a first light-blocking pattern disposed to overlap the second refractive pattern or the first refractive pattern.

5. The display device of claim 4,
wherein the first refractive pattern or the second refractive pattern is disposed to cover the first light-blocking pattern.

6. The display device of claim 1,
wherein the first reflective side surface and the second reflective side surface each comprise an inclined surface.

7. The display device of claim 1,
wherein the first penetration area and the second penetration area each overlap an emission area of the organic light-emitting diode.

8. The display device of claim 1,
wherein the first penetration area and the second penetration area overlap each other.

9. The display device of claim 1,
wherein a width of the first penetration area is identical to a width of the second penetration area.

10. The display device of claim 1,
wherein a width of the first penetration area is greater than a width of the second penetration area.

11. The display device of claim 1,
further comprising a first planarizing layer formed to cover the first refractive pattern.

12. The display device of claim 11,
wherein a refractive index of the first planarizing layer is different from a refractive index of the first refractive pattern.

13. The display device of claim 1,
further comprising a second planarizing layer formed to cover the second refractive pattern.

14. The display device of claim 13,
wherein a refractive index of the second planarizing layer is different from a refractive index of the second refractive pattern.

15. The display device of claim 1,
wherein a width of the first refractive pattern between the pixel and an adjacent pixel is identical to a width of the second refractive pattern between the pixel and the adjacent pixel.

16. The display device of claim 1,
wherein a width of the first refractive pattern between the pixel and an adjacent pixel is smaller than a width of the second refractive pattern between the pixel and the adjacent pixel.

17. The display device of claim 4,
wherein the width of the first refractive pattern between the pixel and an adjacent pixel is greater than the width of the first light-blocking pattern between the pixel and the adjacent pixel.

18. The display device of claim 1,
further comprising a third refractive pattern between the second refractive pattern and the encapsulation member.

19. The display device of claim 1,
wherein the second refractive pattern covers a second light-blocking pattern,
the first refractive pattern covers a first light-blocking pattern, and
a width of the second light-blocking pattern between the pixel and an adjacent pixel is identical to a width of the first light-blocking pattern between the pixel and the adjacent pixel.

20. An electronic device comprising:
a display module, a processor, a memory and a power module,
wherein the display module comprises:
a substrate;
a pixel layer disposed on the substrate and comprising a pixel, the pixel comprising an organic light-emitting diode;
an encapsulation member that seals the pixel layer; and
a refractive layer disposed on the encapsulation member and comprising a second refractive pattern and a first refractive pattern,
wherein the second refractive pattern comprises a second penetration area through which a first portion of light emitted from the organic light-emitting diode passes and a second reflective side surface that reflects a second portion of the light emitted from the organic light-emitting diode, the first and second portions of the light emitted from the organic light emitting diode forming transmitted light, and
the first refractive pattern is disposed to overlap the second refractive pattern and comprises a first penetration area through which a first portion of the transmitted light passes and a first reflective side surface that reflects a second portion of the transmitted light.
